(19) United States
(12) Patent Application Publication
(10) Pub. No.: US 2026/0324315 A1
(43) Pub. Date: Oct. 15, 2026

(54) SURFACE MODIFICATION OF PHOTORESIST FOR DIRECTED SELF-ASSEMBLY

(71) Applicant: TOKYO Electron Limited, Tokyo (JP)

(72) Inventors: Dustin Janes, Albany, NY (US); Kathleen McInerney, Albany, NY (US)

(21) Appl. No.: 19/637,801

(22) Filed: Apr. 2, 2026

Related U.S. Application Data
(60) Provisional application No. 63/785,768, filed on Apr. 9, 2025.

(51) Int. Cl. H10P 14/68; H10P 14/60

(52) U.S. Cl. CPC H10P 14/683; H10P 14/6342; H10P 14/6538; H10P 14/6546

(57) ABSTRACT

In an embodiment, a method is provided for processing a substrate. The method includes providing a substrate including a relief pattern disposed over an underlayer, where the relief pattern includes photoresist. The method includes selectively depositing a polymer layer over exposed surfaces of the relief pattern to modify a surface property of the relief pattern. The method further includes depositing a block copolymer layer over the polymer layer and exposed surfaces of the underlayer, the block copolymer layer including a first block monomer and a second block monomer that are chemically distinct. The method includes annealing the block copolymer layer to induce phase separation into first domains and second domains, where the first domains form over the polymer layer and the second domains form over the underlayer.

### CROSS-REFERENCE TO RELATED APPLICATIONS

This application claims the benefit of U.S. Provisional Application No. 63/785,768, filed on Apr. 9, 2025, which application is hereby incorporated herein by reference.

### TECHNICAL FIELD

The present invention relates generally to a method for semiconductor device fabrication, and, in particular embodiments, to a method for directed self-assembly.

### BACKGROUND

Fabricating semiconductor devices includes patterning a wafer surface to create various trenches, holes, and openings in underlying layers. Lithographic tools face challenges in creating patterns having critical dimensions that meet design specifications. Due to resolution limitations of patterning photoresists, patterns developed from photoresists may not have lines, trenches, and holes that are sufficiently small, smooth, and defect-free to meet design specifications.

Directed self-assembly (DSA) has been identified as a method to form more densely packed devices. The DSA process may be controlled by the molecular weight of the block copolymer mixture, which can be set to a desired dimension that may be smaller than dimensions achievable with optical lithography. Directed self-assembly allows forming small device elements using self-assembling block copolymers along with a guide pattern formed using a lithography process. Directed self-assembly, however, has challenges for achieving reliable patterning with low defectivity.

### SUMMARY

In accordance with one aspect of the present invention, a method is provided for processing a substrate. The method includes providing a substrate including a relief pattern disposed over an underlayer, where the relief pattern includes photoresist. The method further includes selectively depositing a polymer layer over exposed surfaces of the relief pattern to modify a surface property of the relief pattern, and depositing a block copolymer layer over the polymer layer and exposed surfaces of the underlayer, where the block copolymer layer includes a first block monomer and a second block monomer that are chemically distinct. The method further includes annealing the block copolymer layer to induce phase separation into first domains and second domains, where the first domains are formed from the first block monomer and the second domains are formed from the second block monomer, and where the first domains form over the polymer layer and the second domains form over the underlayer.

In accordance with another aspect of the present invention, a method is provided for processing a substrate. The method includes forming a relief pattern over an underlayer on a substrate, where the relief pattern includes a photoresist having exposed surfaces with functional groups, and depositing a polymer layer over the relief pattern, the polymer layer including reactive groups configured to react with the functional groups. The method further includes thermally treating the substrate to cause chemical reaction between the reactive groups and the functional groups, removing unreacted portions of the polymer layer from the substrate, and depositing a block copolymer layer over the polymer layer and a surface of the underlayer, the copolymer layer including a first block monomer and a second block monomer. The method further includes annealing the block copolymer layer to cause selective segregation of the first block monomer to the polymer layer and selective segregation of the second block monomer to the underlayer.

In accordance with yet another aspect of the present invention, a method is provided for processing a substrate. The method includes providing a substrate including a patterned photoresist disposed over an underlayer, where the patterned photoresist includes exposed surfaces with hydrogen bonding groups, and depositing a polymer layer over the exposed surfaces, the polymer layer including complementary hydrogen bonding groups. The method further includes thermally treating the substrate to cause the polymer layer to adsorb onto the exposed surfaces through hydrogen bonding between the hydrogen bonding groups and the complementary hydrogen bonding groups, removing non-adsorbed portions of the polymer layer from the substrate, and depositing a block copolymer layer over the patterned photoresist with the polymer layer and over exposed surfaces of the underlayer, where the block copolymer layer includes a first block monomer and a second block monomer that are chemically distinct. The method further includes annealing the block copolymer layer to induce phase separation into first domains consisting essentially of the first block monomer and second domains consisting essentially of the second block monomer, where the first domains form over the polymer layer and the second domains form over the underlayer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1H illustrate cross-sectional views of a method for processing a substrate using surface-modified photoresist for directed self-assembly, in accordance with one or more embodiments;

FIGS. 2A-2D illustrate top views of the substrate at various stages of the method shown in FIGS. 1A-1H, in accordance with one or more embodiments;

FIGS. 3A-3C illustrate alternative top views of the substrate at various stages of the method shown in FIGS. 1A-1H, in accordance with one or more embodiments;

FIGS. 4A-4B illustrate cross-sectional views of alternative substrate configurations for directed self-assembly, in accordance with one or more embodiments; and

FIG. 5 illustrates a flowchart of a method for processing a substrate using surface-modified photoresist for directed self-assembly, in accordance with one or more embodiments.

Corresponding numerals and symbols in different figures generally refer to corresponding parts unless otherwise indicated. The figures are drawn to clearly illustrate the relevant aspects of the embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

Directed self-assembly (DSA) has potential applications to overcome challenges in extreme ultraviolet (EUV) lithography. Track rectification process flows may use relatively thin EUV photoresists as a chemical guiding pattern for directed self-assembly. However, surface energies of these EUV photoresists are not optimized for directed self-assembly applications. The chemical structure of photoresists is optimized for lithographic performance, including properties such as sensitivity, resolution, line edge roughness, line width roughness, defect density, and etch resistance. Changing the formulation of EUV photoresists to improve DSA properties may result in a tradeoff of weaker performance as a photoresist for printing patterns. EUV photoresist manufacturers cannot tailor surface energy of developed resist for DSA without sacrificing more important properties such as sensitivity.

Embodiments of the disclosure provide methods for modifying photoresists to improve directed self-assembly performance. Embodiments herein modify surfaces of EUV photoresists after pattern development to make surface energy more favorable to guide self-assembly of block copolymers. In various embodiments, the approach may graft brushes or small molecules via chemical reactions or irreversible adsorption to a developed photoresist pattern to improve its performance in EUV rectification applications of directed self-assembly. The surface modification may be performed after the photoresist has been exposed and developed into a relief pattern, thereby decoupling surface energy optimization from EUV resist formulation.

Embodiments of the disclosure decouple surface energy from EUV photoresist formulation and allow for independent optimization via brush chemistry. The modified photoresist surfaces may provide better self-assembly and lower defectivity compared to unmodified photoresist surfaces. In various embodiments, the approach may enable rectification of EUV photoresist patterns with low dose and defectivity at small pitch (e.g., 28 nanometer pitch and smaller) for back-end-of-line logic and dynamic random-access memory applications. The surface-modified photoresist patterns may result in fewer defects, reduced roughness, and faster self-assembly times compared to using unmodified photoresist as a guiding pattern.

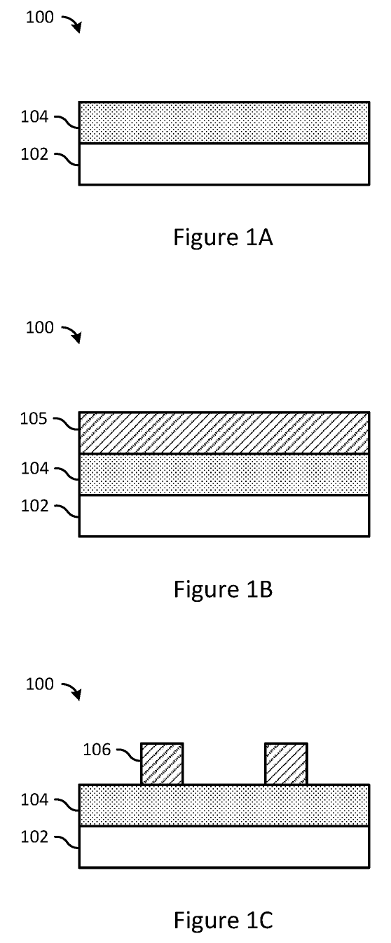

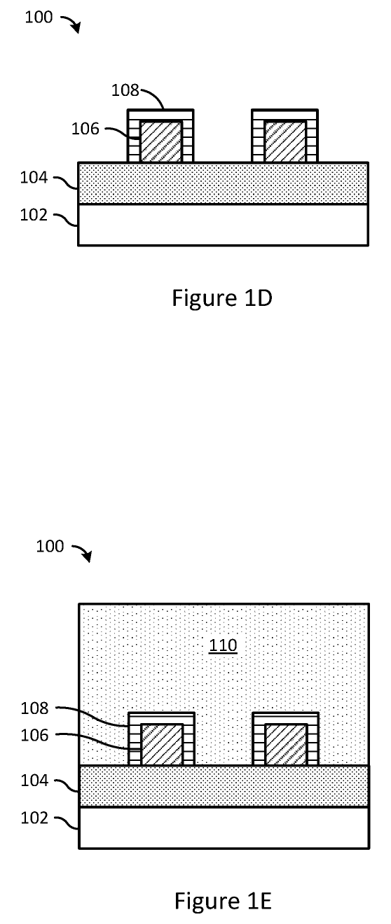

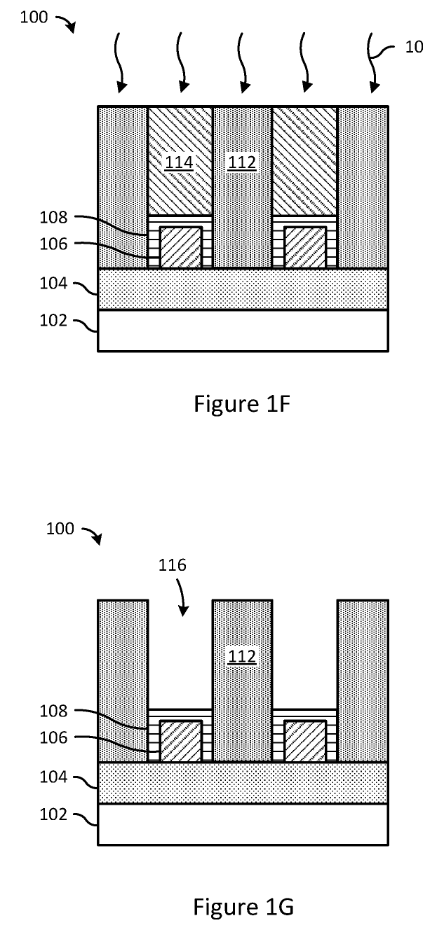

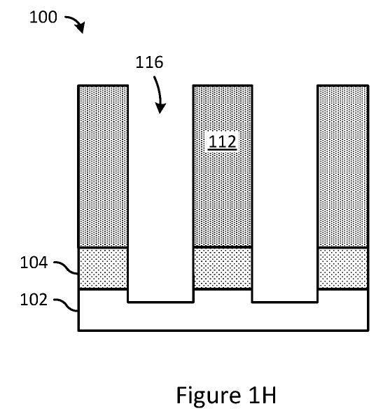

FIGS. 1A-1H illustrate cross-sectional views of a method for processing a substrate using surface-modified photoresist for directed self-assembly, in accordance with various embodiments.

In FIG. 1A, a substrate 100 is provided. The substrate 100 may comprise a wafer 102 and an underlayer 104 disposed over the wafer 102. The wafer 102 may comprise various materials suitable for semiconductor device fabrication. In an embodiment, the wafer 102 may comprise silicon, gallium arsenide, silicon carbide, glass, sapphire, or other suitable substrate materials. The wafer 102 may include previously formed device structures such as logic circuits, memory arrays, transistors, interconnect structures, or other device regions. In various embodiments, the wafer 102 may include one or more hardmask layers such as silicon nitride, silicon oxynitride, titanium nitride, amorphous carbon, spin-on-carbon, amorphous silicon, spin-on-glass, silicon oxide, or other hardmask materials disposed over a base substrate. In various embodiments, the wafer 102 may be processed for back-end-of-line applications or front-end-of-line applications.

The underlayer 104 may be disposed over the wafer 102 to provide a surface for subsequent processing steps. In various embodiments, the underlayer 104 may comprise a cross-linked polymer configured to be preferentially wetted by one block of a block copolymer. The cross-linked polymer may be formulated to exhibit a target water contact angle (e.g., about 85-90 degrees), providing surface energy characteristics suitable for guiding directed self-assembly. In an embodiment, the underlayer 104 may comprise cross-linked polystyrene. The underlayer 104 may be deposited by spin coating a polymer solution onto the wafer 102, followed by thermal treatment to induce cross-linking. In an embodiment, the underlayer 104 may be baked at a temperature between 200°C and 350°C to promote cross-linking reactions. Alternative materials for the underlayer 104 may include other cross-linked polymers, or any material that exhibits preferential wetting by one block of a block copolymer. The underlayer 104 may have a thickness between 10 nanometers and 100nanometers.

FIG. 1B illustrates the substrate 100 after deposition of a photoresist layer 105. The photoresist layer 105 may be deposited over the underlayer 104. In an embodiment, the photoresist layer 105 may be applied by spin coating a photoresist solution onto the substrate 100. The spin coating process may be performed in a track system or coater-developer tool. After deposition, the photoresist layer 105 may be subjected to a post-application bake to remove solvents and stabilize the film. The post-application bake may be performed at a temperature between 80°C and 150°C for a duration between 30 seconds and 5 minutes.

The photoresist layer 105 may be formulated to have photosensitivity to extreme ultraviolet radiation. In various embodiments, the photoresist layer 105 may comprise a chemically amplified resist, a multi-trigger resist, a metal-oxide resist, or other photoresist formulations suitable for extreme ultraviolet lithography. The photoresist layer 105 may be optimized for lithographic performance, including properties such as sensitivity, resolution, line edge roughness, line width roughness, defect density, and etch resistance. The photoresist layer 105 may be a positive-tone resist or a negative-tone resist. In a positive-tone resist, exposed regions become more soluble in developer, while in a negative-tone resist, exposed regions become less soluble in developer. The photoresist layer 105 may have a thickness suitable for forming fine-pitch patterns. In an embodiment, the photoresist layer 105 may have a thickness of 10nanometers or less.

FIG. 1C illustrates the substrate 100 after exposure and development of the photoresist layer 105 to form a relief pattern 106. The photoresist layer 105 may be exposed to a pattern of extreme ultraviolet radiation through a mask or reticle. The exposure may be performed using an extreme ultraviolet lithography tool with a wavelength of approximately 13.5 nanometers. In an embodiment, the exposure dose may be between 26 millijoules per square centimeter and 38 millijoules per square centimeter, although the dose may vary depending on the specific photoresist formulation. The EUV exposure causes chemical changes in the photoresist layer 105, resulting in solubility differences between exposed and unexposed regions.

Following exposure, the photoresist layer 105 may be subjected to a post-exposure bake. The post-exposure bake may promote chemical reactions initiated by the exposure, such as acid-catalyzed deprotection reactions in chemically amplified resists. The post-exposure bake may be performed at a temperature between 80°C and 150°C for a duration between 30 seconds and 5 minutes. After the post-exposure bake, the photoresist layer 105 may be developed using a developer solution to selectively remove either the exposed or unexposed regions. The developer solution may comprise an aqueous base solution such as tetramethylammonium hydroxide for positive-tone resists, or an organic solvent for negative-tone resists. The development process removes portions of the photoresist layer 105, forming the relief pattern 106.

The relief pattern 106, also referred to as patterned photoresist 106, comprises photoresist features with exposed surfaces. The relief pattern 106 may expose portions of the underlayer 104 between the photoresist features. The relief pattern 106 may contain functional groups on its exposed surfaces that result from the exposure and development processes. In an embodiment where the relief pattern 106 comprises a chemically amplified resist, the exposed surfaces may contain phenol groups resulting from deprotection reactions. In another embodiment, the exposed surfaces may contain carboxylic acid groups resulting from deprotection of ester groups. In an embodiment where the relief pattern 106 comprises a resist with secondary alcohol groups, these groups may be present on the exposed surfaces. In yet another embodiment where the relief pattern 106 comprises a metal-oxide resist, the exposed surfaces may contain metal hydroxyl groups resulting from ligand removal during exposure. These functional groups may be available for subsequent surface modification reactions.

The relief pattern 106 may have a thickness of 30 nanometers or less. In various embodiments, the relief pattern 106 may have a thickness between 5 nanometers and 20 nanometers. In an embodiment, the relief pattern 106 may have a thickness of approximately 10 nanometers or less. The relief pattern 106 may define dense periodic patterns such as line-and-space and hexagonally-packed holes or pillars. The relief pattern 106 may have a pitch of 28 nanometers or smaller, suitable for advanced semiconductor device nodes.

In an embodiment, after forming the relief pattern 106, a hardening process may be performed to enhance the stability of the relief pattern 106. The hardening process may comprise coating a hardening agent, baking at a temperature between 100°C and 300°C in an inert atmosphere, and rinsing to remove excess hardening agent. The hardening process may improve the resistance of the relief pattern 106 to subsequent processing steps.

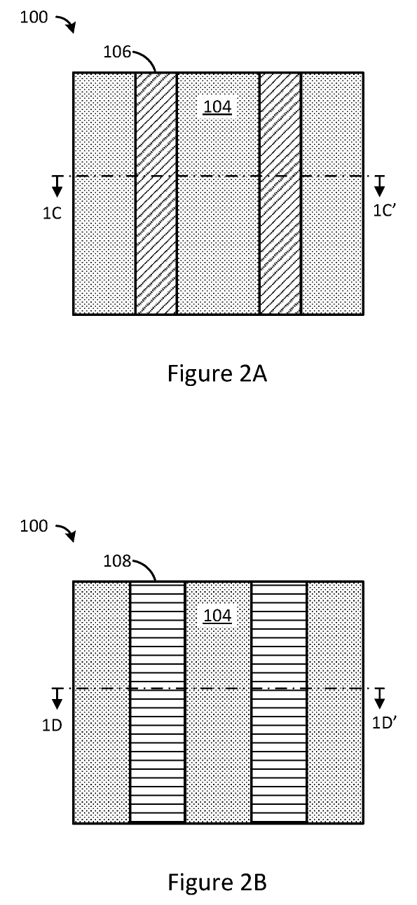

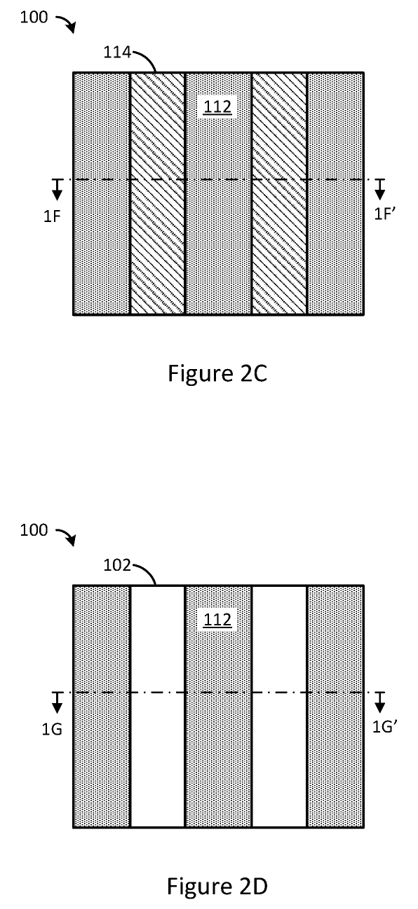

FIG. 2A illustrates a top view of the substrate 100 corresponding to the cross-sectional view along line 1C-1C’ shown in FIG. 1C. The relief pattern 106 may define line patterns or trench patterns extending across the substrate 100. The surface of the underlayer 104 may be exposed through openings between the features of the relief pattern 106. In an embodiment, the relief pattern 106 may comprise parallel lines separated by spaces that expose the underlayer 104. The line patterns may be configured for forming interconnect structures in back-end-of-line applications or other device features.

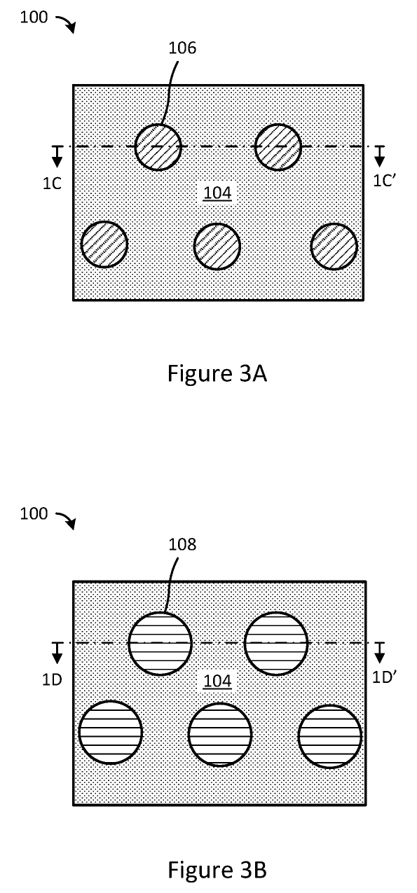

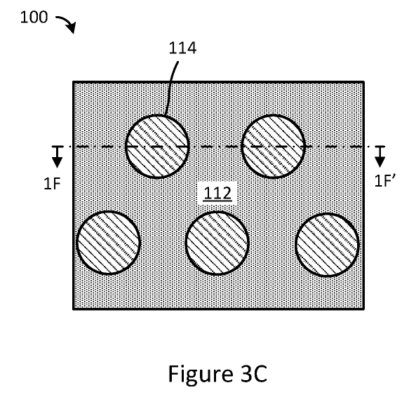

FIG. 3A illustrates another top view of the substrate 100 corresponding to the cross-sectional view shown in FIG. 1C, showing an alternative pattern geometry. The relief pattern 106 may define hexagonally-packed openings through which the surface of the underlayer 104 is exposed. In an embodiment, the relief pattern 106 may comprise a hexagonally-packed array of hole patterns. In another embodiment, the relief pattern 106 may comprise an array of circular, square, or rectangular openings. The openings may be configured for forming contact vias, through-holes, or other device features in semiconductor fabrication.

In FIG. 1D, a polymer layer 108 may be selectively deposited over the relief pattern 106. The polymer layer 108 may be deposited to modify surface properties of the relief pattern 106, thereby optimizing the surface energy for subsequent directed self-assembly processes. The selective deposition of the polymer layer 108 may be achieved through a multi-step process that includes spin coating, thermal treatment, and removal of unreacted material.

In an embodiment, a polymer solution may be spin coated over the substrate 100, depositing polymer material over both the relief pattern 106 and the exposed surfaces of the underlayer 104. The polymer solution may comprise a grafting polymer dissolved in a suitable solvent. The grafting polymer may be formulated to react selectively with functional groups present on the surfaces of the relief pattern 106. In various embodiments, the grafting polymer may comprise reactive groups configured to form covalent bonds with functional groups on the relief pattern 106. The reactive groups may be distributed along the polymer backbone or may be located at chain ends of the grafting polymer.

The composition of the grafting polymer may be selected based on the functional groups present on the relief pattern 106. In an embodiment where the relief pattern 106 comprises phenol groups, the grafting polymer may comprise reactive groups such as acid chloride groups, silyl chloride groups, epoxy groups, or carboxylic acid groups that can react with phenol groups through condensation reactions or ring-opening reactions. In an embodiment where the relief pattern 106 comprises carboxylic acid groups, the grafting polymer may comprise reactive groups such as primary alcohol groups, primary amine groups, acid chloride groups, silyl chloride groups, or epoxy groups that can react with carboxylic acid groups. In an embodiment where the relief pattern 106 comprises secondary alcohol groups, the grafting polymer may comprise reactive groups such as acid chloride groups, silyl chloride groups, epoxy groups, or carboxylic acid groups that can react with secondary alcohol groups. In an embodiment where the relief pattern 106 comprises metal hydroxyl groups, the grafting polymer may comprise reactive groups such as acid chloride groups, silyl chloride groups, epoxy groups, or carboxylic acid groups that can react with metal hydroxyl groups.

The grafting polymer may comprise a base polymer that provides desired surface energy characteristics for directed self-assembly, with a portion of the polymer containing reactive groups for grafting. In an embodiment, the grafting polymer may comprise poly(methyl methacrylate) with a fraction of reactive units distributed along the polymer chain. In various embodiments, the grafting polymer may comprise between 1 percent and 20 percent reactive units, with the remainder comprising non-reactive units that determine the surface energy of the grafted layer. In an embodiment, the grafting polymer may comprise approximately 5 percent reactive units and approximately 95 percent poly(methyl methacrylate) units. Alternatively, the grafting polymer may comprise a polymer with reactive end groups, such as poly(methyl methacrylate) terminated with a carboxylic acid group, a primary amine group, or other reactive functionality.

Following spin coating, the substrate 100 may be thermally treated to promote chemical reactions between the reactive groups of the grafting polymer and the functional groups of the relief pattern 106. The thermal treatment may be performed on a bake plate or in an oven within the track system. In an embodiment, the thermal treatment may be performed at a temperature between 200°C and 300°C. In various embodiments, the thermal treatment may be performed at approximately 250°C. The thermal treatment may be conducted in an inert atmosphere such as nitrogen to prevent oxidation or other unwanted side reactions. The duration of the thermal treatment may be between 1 minute and 30 minutes. In an embodiment, the thermal treatment may be performed for approximately 5 minutes. The thermal treatment provides sufficient thermal energy to overcome activation barriers for the grafting reactions, enabling covalent bond formation between the reactive groups and the functional groups.

The selectivity of grafting to the relief pattern 106 rather than to the underlayer 104 may result from the difference in surface chemistry between these two materials. The underlayer 104, which may comprise cross-linked polystyrene, may lack reactive functional groups that can participate in grafting reactions with the reactive groups of the grafting polymer. The cross-linking of the underlayer 104 may consume reactive groups that were present in the precursor polymer, rendering the surface of the underlayer 104 relatively inert to the grafting chemistry. In contrast, the relief pattern 106 may contain functional groups such as phenol, carboxylic acid, secondary alcohol, or metal hydroxyl groups that readily react with the reactive groups of the grafting polymer under the thermal treatment conditions. This difference in reactivity enables selective grafting of the polymer layer 108 onto the relief pattern 106.

After the thermal treatment, the substrate 100 may be subjected to a rinse process to remove ungrafted polymer from the substrate 100. The rinse process may use a solvent that dissolves ungrafted polymer while leaving the grafted polymer layer 108 attached to the relief pattern 106. In an embodiment, the rinse process may use a track-based solvent such as propylene glycol methyl ether acetate, ethyl lactate, n-butyl acetate, γ-butyrolactone, or other suitable solvents or solvent mixtures. The rinse process removes polymer that was deposited on the underlayer 104 and any excess polymer that did not react with the relief pattern 106. The grafted polymer layer 108 remains on the relief pattern 106 due to covalent bonds formed during the thermal treatment. The rinse process may be performed in a development module or rinse module within the track system.

The polymer layer 108 may have a thickness that modifies the surface energy of the relief pattern 106 without substantially altering the dimensions of the relief pattern 106. In various embodiments, the polymer layer 108 may have a thickness between 1 nanometer and 10 nanometers. In an embodiment, the polymer layer 108 may have a thickness of approximately 5 nanometers or less. The thickness of the polymer layer 108 may depend on factors such as the molecular weight of the grafting polymer, the density of reactive groups, the grafting reaction efficiency, and the thermal treatment conditions. A polymer layer 108 that is too thin may have pinhole defects where surface energy is not well-controlled, while a polymer layer 108 that is too thick may interfere pattern transfer processes.

In an alternative embodiment, the polymer layer 108 may be formed through irreversible physical adsorption rather than covalent grafting. In this embodiment, the grafting polymer may comprise hydrogen bonding groups that form strong hydrogen bonds with complementary hydrogen bonding groups on the relief pattern 106. The hydrogen bonding groups may comprise hydrogen bond donors such as hydroxyl groups, amine groups, or carboxylic acid groups, or hydrogen bond acceptors such as carbonyl groups, ether groups, or amine groups. The relief pattern 106 may comprise complementary hydrogen bonding groups that interact with the hydrogen bonding groups of the grafting polymer. During the thermal treatment, the grafting polymer may adsorb onto the surface of the relief pattern 106 through multiple hydrogen bonding interactions. These hydrogen bonding interactions may be sufficiently strong to resist removal during the subsequent rinse process, resulting in an irreversibly adsorbed polymer layer 108. The selectivity of adsorption to the relief pattern 106 rather than the underlayer 104 may result from differences in the density or type of hydrogen bonding groups on these surfaces.

The polymer layer 108 modifies the surface energy of the relief pattern 106 to make it more favorable for guiding directed self-assembly of block copolymers. The modified surface energy may provide preferential wetting by one block of a block copolymer system, enabling the relief pattern 106 to function as a chemical guiding pattern. The surface modification decouples the optimization of surface energy from the formulation of the photoresist used to form the relief pattern 106, allowing independent optimization of lithographic performance and directed self-assembly compatibility.

FIG. 2B illustrates a top view of the substrate 100 corresponding to the cross-sectional view along line 1D-1D’ shown in FIG. 1D. The polymer layer 108 may be selectively disposed on the line patterns or trench patterns of the relief pattern 106. The polymer layer 108 may conformally cover the top surfaces and sidewalls of the relief pattern 106. The underlayer 104 remains exposed in the spaces between the features of the relief pattern 106, with ungrafted polymer having been removed during the rinse process. The selective disposition of the polymer layer 108 on the relief pattern 106 creates a chemical contrast pattern with alternating regions of different surface energies.

FIG. 3B illustrates another top view of the substrate 100 corresponding to the cross-sectional view shown in FIG. 1D, showing the polymer layer 108 on an alternative pattern geometry. The polymer layer 108 may be selectively disposed on the hexagonally-packed features of the relief pattern 106. The polymer layer 108 may cover the surfaces of the relief pattern 106 surrounding the openings, while the underlayer 104 remains exposed within the openings. The chemical contrast between the polymer layer 108 and the exposed underlayer 104 may guide subsequent block copolymer assembly.

FIG. 1E illustrates the substrate 100 after deposition of a block copolymer layer 110 over the polymer layer 108 and the exposed surfaces of the underlayer 104. The block copolymer layer 110 may comprise a first block monomer and a second block monomer that are chemically distinct and covalently bonded together. In an embodiment, the first block monomer may comprise poly(methyl methacrylate) and the second block monomer may comprise polystyrene. In various embodiments for patterning applications at pitches of 24 nanometers and below, the block copolymer may comprise high-chi block copolymers with greater segregation strength than polystyrene-block-poly(methyl methacrylate). In various embodiments, alternative block copolymer systems may include polystyrene-block-poly(dimethylsiloxane), polystyrene-block-poly(ethylene oxide), polystyrene-block-poly(2-vinylpyridine), polystyrene-block-poly(4-hydroxystyrene), poly(methyl methacrylate)-block-poly(4-hydroxystyrene), polystyrene-block-poly(lactide), or other block copolymer combinations with sufficient chemical incompatibility to enable phase separation. The selection of the block copolymer system may determine the appropriate composition for the polymer layer 108 and the underlayer 104 to achieve preferential wetting by the respective blocks. The block copolymer may be selected to have a molecular weight that determines the natural periodicity of phase-separated domains, enabling formation of features smaller than the pitch of the relief pattern 106.

The block copolymer layer 110 may be deposited by spin coating a block copolymer solution onto the substrate 100. The block copolymer solution may comprise the block copolymer dissolved in a suitable solvent such as propylene glycol methyl ether acetate, toluene, or other solvents compatible with the underlying layers. The spin coating process may be performed in a coating module of the track system. The block copolymer layer 110 may have a thickness between 20 nanometers and 100nanometers. In various embodiments, the block copolymer layer 110 may have a thickness between 40 nanometers and 60 nanometers. The thickness of the block copolymer layer 110 may be selected to provide sufficient material for pattern transfer while enabling complete phase separation during thermal annealing. After deposition, the block copolymer layer 110 may be subjected to a soft bake to remove residual solvent.

FIG. 1F illustrates the substrate 100 after a thermal annealing process 10 to the block copolymer layer 110 to induce phase separation into first domains 114 and second domains 112. The thermal annealing process drives self-assembly of the block copolymer by providing thermal energy for polymer chain mobility and reorganization. The annealing may be performed on a bake plate or in an oven within the track system. In an embodiment, the thermal annealing may be performed at a temperature between 250°C and 300°C. The annealing temperature may be above the glass transition temperatures of both blocks to enable sufficient chain mobility for phase separation. The duration of the thermal annealing may be at least 1 minute. In various embodiments, the duration may range from 1 minute to 12 hours depending on the block copolymer molecular weight and the degree of chemical contrast in the guiding pattern.

During thermal annealing, the chemically distinct first block monomer and second block monomer undergo phase separation due to thermodynamic incompatibility between the two blocks. The first block monomer and second block monomer have different chemical structures and different surface energy preferences, causing them to segregate into separate domains to minimize interfacial energy. The phase separation process may be guided by the chemical pattern created by the polymer layer 108 on the relief pattern 106 and the exposed underlayer 104. The first domains 114 may be formed from segregation of the first block monomer and form over the polymer layer 108, while the second domains 112 may be formed from segregation of the second block monomer and form over the underlayer 104. In one or more embodiments, the first domains 114 may comprise only the first

The selective segregation of the first block monomer to the polymer layer 108 and the second block monomer to the underlayer 104 results from preferential wetting relationships between the blocks and the underlying surfaces. In an embodiment where the first block monomer comprises poly(methyl methacrylate) or a related material similar to that of the polymer layer 108, the first block monomer may preferentially wet the polymer layer 108 due to favorable enthalpic interactions or reduced interfacial energy between chemically similar materials. The surface energy of the polymer layer 108 may be tailored through selection of the grafting polymer composition to promote preferential wetting by the first block monomer.

The second block monomer may preferentially wet the underlayer 104 due to favorable surface energy matching. In an embodiment where the second block monomer comprises polystyrene similar with the underlayer 104, the chemical similarity and surface energy compatibility between the second block monomer and the underlayer 104 promote preferential wetting. The underlayer 104 may be formulated to have a surface energy and chemical composition that matches or closely resembles the second block monomer. In various embodiments, the underlayer 104 may comprise the same chemical structure as the second block monomer in cross-linked form, ensuring strong preferential wetting by the second block monomer.

The preferential wetting relationships guide the orientation and alignment of the phase-separated domains during thermal annealing. The first domains 114 align with the polymer layer 108 on the relief pattern 106, while the second domains 112 align with the exposed underlayer 104. This guided self-assembly process enables formation of well-ordered periodic structures with reduced defects compared to unguided self-assembly. The chemical contrast between the polymer layer 108 and the underlayer 104 provides sufficient driving force to overcome defects or irregularities in the relief pattern 106, resulting in improved pattern quality with reduced line edge roughness and line width roughness.

The first domains 114 and second domains 112 may form alternating lamellar structures, cylindrical structures, or other morphologies depending on the volume fraction of the first block monomer and second block monomer in the block copolymer. In an embodiment, the block copolymer may be a symmetric block copolymer with approximately equal volume fractions of the first block monomer and second block monomer, resulting in lamellar domain structures. The periodicity of the alternating domains may be determined by the molecular weight of the block copolymer, enabling pitch multiplication relative to the pitch of the relief pattern 106.

FIG. 2C illustrates a top view of the substrate 100 corresponding to the cross-sectional view along line 1F-1F’ shown in FIG. 1F. The first domains 114 may form over the line patterns or trench patterns of the relief pattern 106 with the polymer layer 108, while the second domains 112 may form over the exposed underlayer 104 in the spaces between the features of the relief pattern 106. The alternating first domains 114 and second domains 112 create a pattern with reduced pitch compared to the relief pattern 106, demonstrating pitch multiplication through directed self-assembly.

FIG. 3C illustrates another top view of the substrate 100 corresponding to the cross-sectional view shown in FIG. 1F, showing the phase-separated domains on an alternative pattern geometry. The first domains 114 may form over the hexagonally-packed features of the relief pattern 106 with the polymer layer 108, while the second domains 112 may form within the openings of the relief pattern 106 over the exposed underlayer 104. The guided self-assembly process creates well-ordered domain structures that conform to the geometry of the underlying chemical pattern.

FIG. 1G illustrates the substrate 100 after selective removal of the first domains 114 to form openings 116. The selective removal process exploits the etch selectivity between the first block monomer and the second block monomer of the block copolymer. The first block monomer may be etched faster than the second block monomer under predetermined etch chemistries based on the different chemicals between the first block monomer and the second block monomer. In some embodiments, the selective removal may be performed using a dry etch process with an etch chemistry that preferentially removes the first block monomer while leaving the second block monomer substantially intact. In various embodiments, the selective removal may use a plasma etch process with oxygen-containing or fluorine-containing gases. The removal of the first domains 114 exposes underlying portions of the polymer layer 108 and creates the openings 116 that extend through the block copolymer layer 110.

The second domains 112 remain on the substrate 100 after the selective removal process, forming a patterned etch mask. The second domains 112 protect underlying regions of the underlayer 104 and the wafer 102 during subsequent pattern transfer steps. The patterned etch mask defined by the second domains 112 may have a finer pitch than the original relief pattern 106, demonstrating pitch multiplication achieved through directed self-assembly.

FIG. 1H illustrates the substrate 100 after etching through the polymer layer 108, the relief pattern 106, the underlayer 104, and into the wafer 102 using the second domains 112 as the patterned etch mask. The etching process transfers the pattern defined by the second domains 112 into the underlying layers. The openings 116 may extend through multiple layers to create trenches, vias, or other features in the wafer 102. In various embodiments, the etching process may use a single etch chemistry to etch through the organic layers including the polymer layer 108, the relief pattern 106, and the underlayer 104. The polymer layer 108, the relief pattern 106, and the underlayer 104 may all comprise organic materials that can be etched using similar etch chemistries, enabling use of a single gas chemistry for pattern transfer through these layers.

In an embodiment, the etching process may use a dry etch chemistry comprising oxygen, fluorine-containing gases, or other reactive species suitable for etching organic materials. The etch chemistry may be selected to provide sufficient etch rate through the polymer layer 108, the relief pattern 106, and the underlayer 104 while maintaining adequate selectivity to the second domains 112. The relatively thin thicknesses of the polymer layer 108 and the relief pattern 106 may provide sufficient etch budget even if the selectivity between the second domains 112 and these layers is moderate. The block copolymer layer 110 may have a thickness between 40 nanometers and 60 nanometers, providing substantial etch budget for transferring the pattern through the thinner underlying layers.

After etching through the organic layers, the etch chemistry may be switched to etch into the wafer 102 or hardmask layers within the wafer 102. In an embodiment where the wafer 102 comprises silicon nitride or silicon oxynitride hardmask layers, the etch chemistry may be switched to a fluorine-based chemistry optimized for etching these materials. The second domains 112 and the relief pattern 106 may serve as an etch mask during the hardmask open process.

FIG. 2D illustrates a top view of the substrate 100 corresponding to the cross-sectional view shown in FIG. 1G along line 1G-1G’. The second domains 112 form a patterned etch mask with line patterns or other features that define the locations of the openings 116. The pattern defined by the second domains 112 may have a reduced pitch compared to the original relief pattern 106, enabling formation of finer features through the directed self-assembly process.

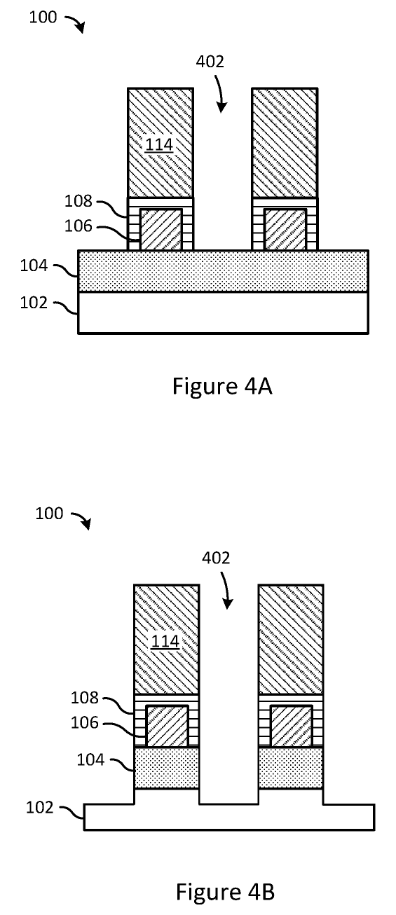

FIGS. 4A and 4B illustrate an alternative embodiment where the second domains 112 are selectively removed instead of the first domains 114 as illustrated in FIGS. 1G and 1H. In FIG. 4A, the second domains 112 may be selectively removed to form openings 402. The selective removal process may exploit etch selectivity between the second block monomer and the first block monomer, enabling selective removal of the second domains 112 while leaving the first domains 114 substantially intact. The removal of the second domains 112 exposes underlying portions of the underlayer 104 within the openings 402.

FIG. 4B illustrates the substrate 100 after etching through the underlayer 104 using the first domains 114 as a patterned etch mask. The etching process transfers the pattern defined by the first domains 114 into the underlayer 104 and potentially into the wafer 102. The openings 402 may extend through the underlayer 104 to create trenches, vias, or other features. The first domains 114 protect underlying regions during the etch process. The polymer layer 108 and the relief pattern 106 may also serve as part of the etch mask stack during pattern transfer.

Following the etching processes shown in FIG. 1H or FIG. 4B, the remaining organic materials may be removed from the substrate 100. The second domains 112 or first domains 114, the polymer layer 108, the relief pattern 106, and any remaining portions of the underlayer 104 may be stripped using an ashing process, a wet strip process, or other suitable removal techniques. The substrate 100 may then be transferred to subsequent processing steps such as deposition, planarization, or additional patterning operations. The patterned features created in the wafer 102 may serve as templates for forming device structures such as interconnect lines, vias, capacitor structures, or other semiconductor device elements.

In various embodiments, the processes described with reference to FIGS. 1A through 1H may be performed entirely within a track processing system. The track system may comprise multiple processing modules including coating modules for applying the photoresist layer 105, the polymer layer 108, and the block copolymer layer 110, thermal processing modules such as bake plates or ovens for performing post-application bakes, post-exposure bakes, grafting reactions, and thermal annealing, development modules for developing the photoresist layer 105, and rinse modules for removing ungrafted polymer. The track processing system may enable the complete process flow from photoresist coating through block copolymer annealing without requiring transfer of the substrate 100 to separate etch tools or strip tools. This integration may reduce process complexity, minimize contamination risks, and improve throughput compared to conventional directed self-assembly integration schemes that require multiple tool transfers.

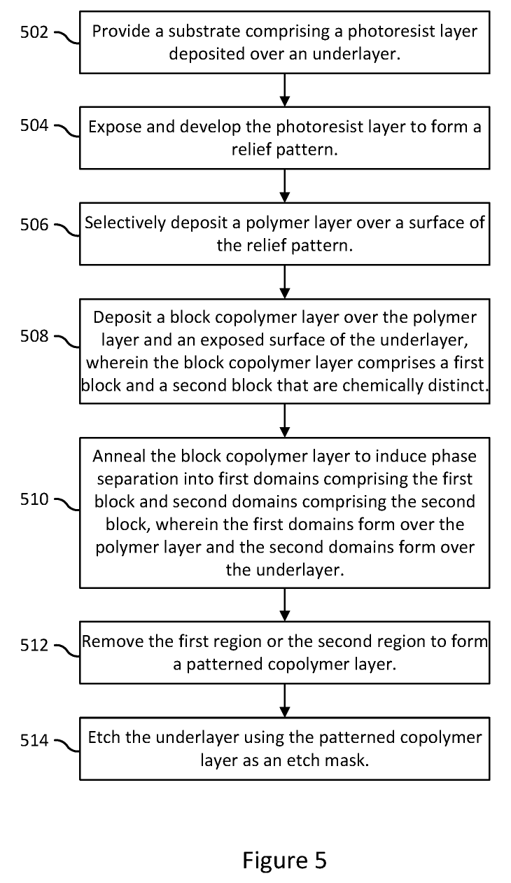

FIG. 5 illustrates a flowchart of a method for processing a substrate using surface-modified photoresist for directed self-assembly, in accordance with one or more embodiments. The method may enable formation of fine-pitch patterns through a combination of extreme ultraviolet lithography and directed self-assembly with optimized surface properties.

At block 502, a substrate comprising a photoresist layer deposited over an underlayer may be provided. The substrate may be the substrate 100 as described with reference to FIG. 1A. The substrate may comprise a wafer 102 and an underlayer 104 disposed over the wafer 102. The wafer 102 may comprise materials and structures as described with reference to FIG. 1A, including silicon, gallium arsenide, or other substrate materials, and may include hard mask layers or device regions. The underlayer 104 may comprise materials and have characteristics as described with reference to FIG. 1A, such as cross-linked polystyrene or other cross-linked polymers configured to be preferentially wetted by one block of a block copolymer. The photoresist layer may be the photoresist layer 105 as described with reference to FIG. 1B, and may be deposited using similar methods and may comprise similar materials as described with reference to FIG. 1B.

At block 504, the photoresist layer may be exposed and developed to form a relief pattern. The exposure and development process may follow the methods described with reference to FIG. 1C. The photoresist layer 105 may be exposed to a pattern of extreme ultraviolet radiation and developed to form the relief pattern 106 as described with reference to FIG. 1C. The relief pattern 106 may comprise photoresist features with exposed surfaces containing functional groups as described with reference to FIG. 1C. The relief pattern 106 may have similar thickness, materials, and functional groups as described with reference to FIG. 1C.

At block 506, a polymer layer may be selectively deposited over a surface of the relief pattern. The selective deposition process may follow the methods described with reference to FIG. 1D. The polymer layer may be the polymer layer 108 as described with reference to FIG. 1D. The selective deposition may comprise spin coating a grafting polymer, thermally treating the substrate to cause chemical reactions or physical adsorption between the grafting polymer and functional groups on the relief pattern, and removing ungrafted polymer, as described with reference to FIG. 1D. The polymer layer 108 may comprise similar materials, reactive groups, and thickness as described with reference to FIG. 1D. The selective grafting or adsorption mechanisms may follow the processes described with reference to FIG. 1D.

At block 508, a block copolymer layer may be deposited over the polymer layer and an exposed surface of the underlayer. The block copolymer layer may be the block copolymer layer 110 as described with reference to FIG. 1E. The deposition process may follow similar methods as described with reference to FIG. 1E, such as spin coating a block copolymer solution. The block copolymer layer may comprise a first block monomer and a second block monomer that are chemically distinct, and may comprise similar materials and thickness as described with reference to FIG. 1E.

At block 510, the block copolymer layer may be annealed to induce phase separation into first domains comprising the first block monomer and second domains comprising the second block monomer. The annealing process may follow the methods and conditions described with reference to FIG. 1F. The first domains may be the first domains 114 consisting essentially of the first block monomer and the second domains may be the second domains 112 consisting essentially of the second block monomer as described with reference to FIG. 1F. The first domains may form over the polymer layer and the second domains may form over the underlayer through preferential wetting relationships as described with reference to FIG. 1F. The phase separation mechanism and guided self-assembly process may follow the description with reference to FIG. 1F.

At block 512, the first region or the second region may be removed to form a patterned copolymer layer. In an embodiment, the first domains 114 may be selectively removed to form the openings 116 as described with reference to FIG. 1G. In an alternative embodiment, the second domains 112 may be selectively removed to form openings 402 as described with reference to FIG. 4A. The selective removal process may exploit etch selectivity between the first block monomer and the second block monomer as described with reference to FIGS. 1G and 4A.

At block 514, the underlayer may be etched using the patterned copolymer layer as an etch mask. In an embodiment, the etching process may follow the methods described with reference to FIG. 1H, where the second domains 112 serve as a patterned etch mask and the etching extends through the polymer layer 108, the relief pattern 106, the underlayer 104, and into the wafer 102. The etching may use similar etch chemistries and processes as described with reference to FIG. 1H. In an alternative embodiment, the etching process may follow the methods described with reference to FIG. 4B, where the first domains 114 serve as a patterned etch mask. Following the etching process, remaining organic materials may be removed and the substrate may be transferred to subsequent processing steps as described with reference to FIGS. 1H and 4B.

While not explicitly shown in the flowchart, the method may be performed entirely within a track processing system without transferring the substrate to an etch tool or strip tool between providing the substrate and annealing the block copolymer layer, as described earlier. The all-track process flow may reduce the number of process steps and tools compared to conventional directed self-assembly integration schemes. Additionally, the method may enable rectification of patterns with reduced line edge roughness, reduced defects, and faster self-assembly times as described in the previous figures. The method may be applicable to forming patterns at 28 nanometer pitch and smaller for back-end-of-line logic and dynamic random-access memory applications.

While the inventive aspects are described primarily in the context of surface modification of photoresists for directed self-assembly in semiconductor patterning, it should also be appreciated that these inventive aspects may apply to various semiconductor fabrication processes requiring precise pattern control and surface energy optimization. In particular, embodiments of this disclosure may similarly apply to pitch multiplication for back-end-of-line metallization, contact and via patterning for advanced logic devices, capacitor formation in dynamic random-access memory, fin patterning in FinFET devices, gate patterning in transistor fabrication, through-silicon via formation in three-dimensional integration, pattern rectification for reducing line edge roughness and line width roughness, and any lithographic application where independent optimization of photoresist performance and directed self-assembly compatibility is beneficial for achieving high-resolution patterns with low defectivity.

Example embodiments of the invention are described below. Other embodiments can also be understood from the entirety of the specification as well as the claims filed herein.

Example 1. A method for processing a substrate, the method including: providing a substrate including a relief pattern disposed over an underlayer, where the relief pattern includes photoresist; selectively depositing a polymer layer over exposed surfaces of the relief pattern to modify a surface property of the relief pattern; depositing a block copolymer layer over the polymer layer and exposed surfaces of the underlayer, the block copolymer layer including a first block monomer and a second block monomer that are chemically distinct; and annealing the block copolymer layer to induce phase separation into first domains and second domains, where the first domains are formed from the first block monomer and the second domains are formed from the second block monomer, and where the first domains form over the polymer layer and the second domains form over the underlayer.

Example 2. The method of example 1, where selectively depositing the polymer layer includes: spin coating the polymer layer over the exposed surfaces of the relief pattern and the exposed surfaces of the underlayer; thermally treating the substrate to cause reactive groups of the polymer layer to react with functional groups of the relief pattern, thereby modifying the surface property of the relief pattern; and removing unreacted portions of the polymer layer from the substrate.

Example 3. The method of one of examples 1 or 2, where the functional groups of the relief pattern include phenol groups, carboxylic acid groups, secondary alcohol groups, or metal hydroxyl groups, and where the reactive groups of the polymer layer include acid chloride groups, silyl chloride groups, epoxy groups, primary alcohol groups, or primary amine groups.

Example 4. The method of one of examples 1 to 3, where the functional groups include hydrogen bonding groups, and where the reactive groups include complementary hydrogen bonding groups configured to form hydrogen bonds with the hydrogen bonding groups.

Example 5. The method of one of examples 1 to 4, where the photoresist is formulated to have photosensitivity to extreme ultraviolet radiation, and where the method further includes, prior to selectively depositing the polymer layer: exposing the photoresist to a pattern of extreme ultraviolet radiation; and developing the photoresist to form the relief pattern.

Example 6. The method of one of examples 1 to 5, where the relief pattern has a thickness of 10 nanometers or less, and where the polymer layer on the relief pattern has a thickness of 10 nanometers or less.

Example 7. The method of one of examples 1 to 6, where the first block monomer includes poly(methyl methacrylate) and the second block monomer includes polystyrene.

Example 8. The method of one of examples 1 to 7, where the method is performed entirely within a track processing system without transferring the substrate to an etch tool or a strip tool between providing the substrate and annealing the block copolymer layer.

Example 9. The method of one of examples 1 to 8, where the underlayer includes a cross-linked polymer.

Example 10. The method of one of examples 1 to 9, further including, after annealing the block copolymer layer: selectively removing the first block monomer or the second block monomer to form a patterned mask; and etching the underlayer using the patterned mask to transfer a pattern into the underlayer.

Example 11. A method for processing a substrate, the method including: forming a relief pattern over an underlayer on a substrate, where the relief pattern includes a photoresist having exposed surfaces with functional groups; depositing a polymer layer over the relief pattern, the polymer layer including reactive groups configured to react with the functional groups; thermally treating the substrate to cause chemical reaction between the reactive groups and the functional groups; removing unreacted portions of the polymer layer from the substrate; depositing a block copolymer layer over the polymer layer and a surface of the underlayer, the copolymer layer including a first block monomer and a second block monomer; and annealing the block copolymer layer to cause selective segregation of the first block monomer to the polymer layer and selective segregation of the second block monomer to the underlayer.

Example 12. The method of example 11, where the functional groups include phenol groups, carboxylic acid groups, secondary alcohol groups, or metal hydroxyl groups.

Example 13. The method of one of examples 11 or 12, where the reactive groups include acid chloride groups, silyl chloride groups, epoxy groups, primary alcohol groups, or primary amine groups.

Example 14. The method of one of examples 11 to 13, where thermally treating the substrate includes heating the substrate to a temperature between 200°C and 300°C in an inert atmosphere for a duration of at least 1 minute.

Example 15. The method of one of examples 11 to 14, where removing unreacted portions of the polymer layer includes rinsing the substrate with a solvent.

Example 16. The method of one of examples 11 to 15, where the photoresist is formulated to have photosensitivity to extreme ultraviolet radiation, and where forming the relief pattern includes: coating the photoresist over the underlayer; exposing the photoresist to a pattern of extreme ultraviolet radiation; and developing the photoresist to form the relief pattern.

Example 17. The method of one of examples 11 to 16, where the relief pattern includes line patterns, via patterns, or trench patterns.

Example 18. A method for processing a substrate, the method including: providing a substrate including a patterned photoresist disposed over an underlayer, where the patterned photoresist includes exposed surfaces with hydrogen bonding groups; depositing a polymer layer over the exposed surfaces, the polymer layer including complementary hydrogen bonding groups; thermally treating the substrate to cause the polymer layer to adsorb onto the exposed surfaces through hydrogen bonding between the hydrogen bonding groups and the complementary hydrogen bonding groups; removing non-adsorbed portions of the polymer layer from the substrate; depositing a block copolymer layer over the patterned photoresist with the polymer layer and over exposed surfaces of the underlayer, where the block copolymer layer includes a first block monomer and a second block monomer that are chemically distinct; and annealing the block copolymer layer to induce phase separation into first domains consisting essentially of the first block monomer and second domains consisting essentially of the second block monomer, where the first domains form over the polymer layer and the second domains form over the underlayer.

Example 19. The method of example 18, where the patterned photoresist is formulated to have photosensitivity to extreme ultraviolet radiation, and where the method further includes, prior to depositing the polymer layer: exposing a photoresist layer to a pattern of extreme ultraviolet radiation; and developing the photoresist layer to form the patterned photoresist.

Example 20. The method of one of examples 18 or 19, where the hydrogen bonding groups include hydrogen bond donors or hydrogen bond acceptors, and where the complementary hydrogen bonding groups include hydrogen bond acceptors or hydrogen bond donors complementary to the hydrogen bonding groups.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-5 may be combined in further embodiments. It is therefore intended that the appended claims encompass any such modifications or embodiments.

What is claimed is:

1. A method for processing a substrate, the method comprising:
providing a substrate comprising a relief pattern disposed over an underlayer, wherein the relief pattern comprises photoresist;
selectively depositing a polymer layer over exposed surfaces of the relief pattern to modify a surface property of the relief pattern;
depositing a block copolymer layer over the polymer layer and exposed surfaces of the underlayer, the block copolymer layer comprising a first block monomer and a second block monomer that are chemically distinct; and
annealing the block copolymer layer to induce phase separation into first domains and second domains, wherein the first domains are formed from the first block monomer and the second domains are formed from the second block monomer, and wherein the first domains form over the polymer layer and the second domains form over the underlayer.

2. The method of claim 1, wherein selectively depositing the polymer layer comprises:
spin coating the polymer layer over the exposed surfaces of the relief pattern and the exposed surfaces of the underlayer;
thermally treating the substrate to cause reactive groups of the polymer layer to react with functional groups of the relief pattern, thereby modifying the surface property of the relief pattern; and
removing unreacted portions of the polymer layer from the substrate.

3. The method of claim 2, wherein the functional groups of the relief pattern comprise phenol groups, carboxylic acid groups, secondary alcohol groups, or metal hydroxyl groups, and wherein the reactive groups of the polymer layer comprise acid chloride groups, silyl chloride groups, epoxy groups, primary alcohol groups, or primary amine groups.

4. The method of claim 2, wherein the functional groups comprise hydrogen bonding groups, and wherein the reactive groups comprise complementary hydrogen bonding groups configured to form hydrogen bonds with the hydrogen bonding groups.

5. The method of claim 1, wherein the photoresist is formulated to have photosensitivity to extreme ultraviolet radiation, and wherein the method further comprises, prior to selectively depositing the polymer layer:
exposing the photoresist to a pattern of extreme ultraviolet radiation; and
developing the photoresist to form the relief pattern.

6. The method of claim 1, wherein:
the relief pattern has a thickness of 10 nanometers or less; and
the polymer layer on the relief pattern has a thickness of 10 nanometers or less.

7. The method of claim 1, wherein the first block monomer comprises poly(methyl methacrylate) and the second block monomer comprises polystyrene.

8. The method of claim 1, wherein the method is performed entirely within a track processing system without transferring the substrate to an etch tool or a strip tool between providing the substrate and annealing the block copolymer layer.

9. The method of claim 1, wherein the underlayer comprises a cross-linked polymer.

10. The method of claim 1, further comprising, after annealing the block copolymer layer:
selectively removing the first block monomer or the second block monomer to form a patterned mask; and
etching the underlayer using the patterned mask to transfer a pattern into the underlayer.

11. A method for processing a substrate, the method comprising:
forming a relief pattern over an underlayer on a substrate, wherein the relief pattern comprises a photoresist comprising exposed surfaces with functional groups;
depositing a polymer layer over the relief pattern, the polymer layer comprising reactive groups configured to react with the functional groups;
thermally treating the substrate to cause chemical reaction between the reactive groups and the functional groups;
removing unreacted portions of the polymer layer from the substrate;
depositing a block copolymer layer over the polymer layer and a surface of the underlayer, the copolymer layer comprising a first block monomer and a second block monomer; and
annealing the block copolymer layer to cause selective segregation of the first block monomer to the polymer layer and selective segregation of the second block monomer to the underlayer.

12. The method of claim 11, wherein the functional groups comprise phenol groups, carboxylic acid groups, secondary alcohol groups, or metal hydroxyl groups.

13. The method of claim 11, wherein the reactive groups comprise acid chloride groups, silyl chloride groups, epoxy groups, primary alcohol groups, or primary amine groups.

14. The method of claim 11, wherein thermally treating the substrate comprises heating the substrate to a temperature between 200°C and 300°C in an inert atmosphere for a duration of at least 1 minute.

15. The method of claim 11, wherein removing unreacted portions of the polymer layer comprises rinsing the substrate with a solvent.

16. The method of claim 11, wherein the photoresist is formulated to have photosensitivity to extreme ultraviolet radiation, and wherein forming the relief pattern comprises:
coating the photoresist over the underlayer;
exposing the photoresist to a pattern of extreme ultraviolet radiation; and
developing the photoresist to form the relief pattern.

17. The method of claim 11, wherein the relief pattern comprises line patterns, via patterns, or trench patterns.

18. A method for processing a substrate, the method comprising:
providing a substrate comprising a patterned photoresist disposed over an underlayer, wherein the patterned photoresist comprises exposed surfaces with hydrogen bonding groups;
depositing a polymer layer over the exposed surfaces, the polymer layer comprising complementary hydrogen bonding groups;
thermally treating the substrate to cause the polymer layer to adsorb onto the exposed surfaces through hydrogen bonding between the hydrogen bonding groups and the complementary hydrogen bonding groups;
removing non-adsorbed portions of the polymer layer from the substrate;
depositing a block copolymer layer over the patterned photoresist with the polymer layer and over exposed surfaces of the underlayer, wherein the block copolymer layer comprises a first block monomer and a second block monomer that are chemically distinct; and
annealing the block copolymer layer to induce phase separation into first domains consisting essentially of the first block monomer and second domains consisting essentially of the second block monomer, wherein the first domains form over the polymer layer and the second domains form over the underlayer.

19. The method of claim 18, wherein the patterned photoresist is formulated to have photosensitivity to extreme ultraviolet radiation, and wherein the method further comprises, prior to depositing the polymer layer:
exposing a photoresist layer to a pattern of extreme ultraviolet radiation; and
developing the photoresist layer to form the patterned photoresist.

20. The method of claim 18, wherein the hydrogen bonding groups comprise hydrogen bond donors or hydrogen bond acceptors, and wherein the complementary hydrogen bonding groups comprise hydrogen bond acceptors or hydrogen bond donors complementary to the hydrogen bonding groups.
